(19) United States
(12) Patent Application Publication
(10) Pub. No.: US 2008/0164503 A1
(43) Pub. Date: Jul. 10, 2008

(54) Ferroelectric Memory Devices Having a Protruding Bottom Electrode and Methods of Forming the Same

(75) Inventors: Suk-Hun Choi, Gyeonggi-do (KR); Chang-Ki Hong, Gyeonggi-do (KR); Jung-Hyeon Kim, Gyeonggi-do (KR); Jun-Young Lee, Gyeonggi-do (KR); Jong-Heun Lim, Seoul (KR); Seong-Kyu Yun, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/970,770

(22) Filed: Jan. 8, 2008

(30) Foreign Application Priority Data
Jan. 8, 2007 (KR) 2007-2089

(51) Int. Cl. G11C 11/22; H01L 29/78; H01L 21/02

(52) U.S. Cl. 257/295; 438/3; 365/145

(57) ABSTRACT

A ferroelectric memory device and methods of forming the same are provided. Forming a ferroelectric device includes forming an insulation layer over a substrate having a conductive region, forming a bottom electrode electrically connected to the conductive region in the insulation layer, recessing the insulation layer, and forming a ferroelectric layer and an upper electrode layer covering the bottom electrode over the recessed insulation layer, The bottom electrode protrudes over an upper surface of the recessed insulation layer.

### CROSS-REFERENCE TO RELATED APPLICATION

This application claims priority under 35 U.S.C. § 119 to Korean Patent Application No. 10-2007-0002089 filed on Jan. 8, 2007 in the Korean Intellectual Property Office, the disclosure of which is incorporated herein by reference in its entirety.

### BACKGROUND OF THE INVENTION

1. Field of the Invention

The present invention relates to semiconductor devices, and, more particularly, to ferroelectric memory devices and methods of forming the same.

2. Description of the Related Art

Generally, semiconductor memory devices may be classified into volatile memory devices and nonvolatile memory devices. A volatile memory device loses data by cutting off the electrical power supply, but a nonvolatile memory device can retain stored data despite electrical power supply being cut off.

A ferroelectric memory device or a ferroelectric random access memory (FRAM) device is a kind of a nonvolatile memory device and does not lose stored data because the ferroelectric material has a spontaneous polarization characteristic. Therefore, the FRAM device may have a superior data-retention characteristic. Furthermore, the FRAM device may be operated at lower power as compared to other nonvolatile memory devices, and the number of data input/output into/from the FRAM device may be remarkably increased.

A ferroelectric memory device may have a capacitor including a bottom electrode, a ferroelectric pattern, and an upper electrode. To form the capacitor, a bottom electrode layer, a ferroelectric layer, an upper electrode layer, and a mask pattern are formed, and then an etch process using the mask pattern as an etch mask may be performed with respect to the upper electrode layer, the ferroelectric layer, and the bottom electrode layer. However, when the bottom electrode layer is etched after the upper electrode layer and the ferroelectric layer are formed, sidewalls of the upper electrode and the ferroelectric pattern may gradually collapse so that a sidewall inclination angle of the capacitor may be lowered from about 80 degrees to about 60 degrees. When the ferroelectric layer is etched at a high temperature, the mask pattern may not fully protect the ferroelectric layer during the high-temperature etch process, so that a sidewall inclination angel of the ferroelectric pattern may be remarkably lowered and etch damage may occur on the ferroelectric pattern. In the case that the ferroelectric capacitor has a low sidewall inclination angle, an effective area of the ferroelectric capacitor having the ferroelectric pattern is decreased. This can result in decrease of capacitance of the ferroelectric capacitor. Furthermore, a data retention characteristic of the ferroelectric pattern may be lowered due to the etch damage.

However, if a thickness of a bottom electrode layer is thinned to shorten an etch time of the bottom electrode layer, other problems such as a lowered operation characteristic of a capacitor may occur.

### SUMMARY

In some embodiments of the present invention, a ferroelectric memory device includes a substrate having a conductive region; an insulation layer on the substrate; a bottom electrode that is electrically connected to the conductive region, protrudes over the insulation layer, and has a bottom surface that is lower than an upper surface of the insulation layer; and a ferroelectric layer and an upper electrode that cover an upper surface and sidewalls of the protruded bottom electrode.

The ferroelectric memory device may further include a bottom electrode contact that is interposed between the conductive region and the bottom electrode, and a width of the bottom electrode may be about the same as a width of the bottom electrode contact. The bottom electrode may have a constant width. The bottom electrode may include ruthenium or iridium.

The insulation layer may include an interlayer dielectric layer and a blocking layer on the interlayer dielectric layer, and a bottom surface of the bottom electrode may be lower than or have about the same height as a bottom surface of the blocking layer. The blocking layer may include titanium oxide, tantalum oxide, and/or silicon nitride. The ferroelectric layer may include a seed layer.

Embodiments of the present invention provide methods of forming a ferroelectric memory device, including forming an insulation layer on a substrate having a conductive region; forming a bottom electrode electrically connected to the conductive region in the insulation layer; recessing the insulation layer; and forming a ferroelectric layer and an upper electrode layer covering the bottom electrode on the recessed insulation layer. The bottom electrode protrudes over an upper surface of the recessed insulation layer.

Forming the insulation layer may include forming an interlayer dielectric layer on the substrate and forming a blocking layer on the interlayer dielectric layer. Forming the bottom electrode may include patterning the interlayer dielectric layer and the blocking layer to form an opening exposing the conductive region; forming a bottom electrode contact contacting the conductive region in a lower region of the opening; and filling the opening on the bottom electrode contact with a conductive material. In other embodiments, forming the bottom electrode may include patterning the interlayer dielectric layer to form a first opening exposing the conductive region; forming a bottom electrode contact contacting the conductive region in the first opening; forming a blocking layer on the interlayer dielectric layer where the bottom electrode contact is formed; patterning the blocking layer to form a second opening exposing the bottom electrode contact; and filling the second opening with a conductive material. A width of the second opening may be greater than a width of the first opening. Recessing the insulation layer may include recessing the blocking layer.

Forming the insulation layer may include forming an interlayer dielectric layer on the substrate; forming a blocking layer on the interlayer dielectric layer; and forming a sacrificial insulation layer on the blocking layer. Forming the bottom electrode may include pattering the interlayer dielectric layer, the blocking layer, and the sacrificial insulation layer to form an opening exposing the conductive region; forming a bottom electrode contact contacting the conductive region in a lower region of the opening; and filling the opening on the bottom electrode contact with a conductive material. In other embodiments, forming the bottom electrode may include patterning the interlayer dielectric layer to form a first opening exposing the conductive region; forming a bottom electrode contact in the first opening; forming the blocking layer and the sacrificial insulation layer on the interlayer dielectric layer where the bottom electrode contact is formed; patterning the blocking layer and the sacrificial insulation layer to form a second opening exposing the bottom electrode contact; and filling the second opening with a conductive material. A width of the second opening may be greater than a width of the first opening. Recessing the insulation layer may include recessing the sacrificial insulation layer. In other embodiments, recessing the insulation layer may include removing the sacrificial insulation layer.

A seed layer for growing the ferroelectric layer may be formed before forming the ferroelectric layer.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain principles of the invention. In the drawings:

FIG. 1 is a sectional view illustrating a ferroelectric memory device according to some embodiments of the present invention;

FIGS. 2 through 5 are sectional views illustrating methods of forming a ferroelectric memory device according to some embodiments of the present invention;

FIGS. 6 through 8 are sectional views illustrating methods of forming a ferroelectric memory device according to further embodiments of the present invention;

FIGS. 9 through 11 are sectional views illustrating methods of forming a ferroelectric memory device according to still further embodiments of the present invention; and

FIGS. 12 and 13 are sectional views illustrating methods of forming a ferroelectric memory device according still further embodiments of the present invention.

### DETAILED DESCRIPTION OF EMBODIMENTS OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout the description of the figures.

It will be understood that when an element is referred to as being “on” another element, it can be directly on the other element or intervening elements may be present. In contrast, when an element is referred to as being “directly on” another element, there are no intervening elements present. It will be understood that when an element is referred to as being “connected” or “coupled” to another element, it can be directly connected or coupled to the other element or intervening elements may be present. In contrast, when an element is referred to as being “directly connected or coupled” to another element, there are no intervening elements present. Furthermore, “connected” or “coupled” as used herein may include wirelessly connected or coupled. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first layer could be termed a second layer, and, similarly, a second layer could be termed a first layer without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions integers, steps, operations, elements, components, and/or groups thereof.

Furthermore, relative terms, such as “lower” or “bottom” and “upper” or “top,” may be used herein to describe one element's relationship to other elements as illustrated in the Figures. It will be understood that relative terms are intended to encompass different orientations of the device in addition to the orientation depicted in the Figures. For example, if the device in one of the figures were turned over, elements described as being on the “lower” side of other elements would then be oriented on “upper” sides of the other elements. The exemplary term “lower”, can therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

In the description, a term “substrate” used herein may include a structure based on a semiconductor, having a semiconductor surface exposed. It should be understood that such a structure may contain silicon, silicon on insulator, silicon on sapphire, doped or undoped silicon, epitaxial layer supported by a semiconductor substrate, or another structure of a semiconductor. And, the semiconductor may be silicon-germanium germanium, or germanium arsenide, not limited to silicon. In addition, the substrate described hereinafter may be one in which regions, conductive layers, insulation layers, their patterns, and/or junctions are formed.

FIG. 1 is a sectional view illustrating a ferroelectric memory device according to some embodiments of the present invention.

Referring to FIG. 1, an active region is defined by a device isolation region 112 formed in the semiconductor substrate 110. A gate electrode 123 is located over the active region by interposing a gate insulation layer 121 between the semiconductor substrate 110 and the gate electrode 123. Impurity-doped regions 125 are located in the active region at both sides of the gate electrode 123. The impurity-doped regions 125 may function as source/drain regions. A capping layer 127 is located over the gate electrode 123 and spacers 129 are located at both sidewalls of the capping layer 127 and the gate electrode 123. The gate electrode 123 is located in the first insulation layer 130.

Contact pads 131 and 132 are located on the impurity-doped regions 125. The contact pads 131 and 132 contact the impurity-doped regions 125 through the first insulation layer 130. The contact pads 131 and 132 may be self-aligned by the spacers 129. A second insulation layer 140, a third insulation layer 150, a fourth insulation layer 160, and a blocking layer 170 are sequentially located on the contact pads 131 and 132. For example, the first through fourth insulation layers 130, 140, 150, and 160 may include a silicon oxide, and the blocking layer 170 may include titanium oxide, tantalum oxide or silicon nitride. A conductive line 152 is located in the third insulation layer 150 and a contact plug 142 electrically connecting the contact pad 131 to the conductive line 152 is located in the second insulation layer 140. The conductive line 152 may be referred to as a bit line or a data line.

A bottom electrode contact 162 is located on the contact pad 132. The bottom electrode contact 162 may contact the contact pad 132 through the second through fourth insulation layers 140, 150, and 160. An upper surface of the bottom electrode contact 162 may be lower than or have about the same height as an upper surface of the fourth insulation layer 160. The bottom electrode contact 162 may include tungsten or doped polysilicon.

A capacitor 180 is located on the bottom electrode contact 162. The capacitor 180 may include a bottom electrode 182, a seed pattern 184, a ferroelectric pattern 186, and an upper electrode 188. The bottom electrode 182 contacts the bottom electrode contact 162 through the blocking layer 170. The bottom electrode 182 protrudes over the blocking layer 170, thereby having an upper surface higher than an upper surface of the blocking layer 170. Furthermore, a sidewall of the bottom electrode 182 may be exposed. A bottom surface of the bottom electrode 182 may be lower than or have about the same height as a bottom surface of the blocking layer 170. A width of the bottom electrode 182 may be about the same as a width of the bottom electrode contact 162. The bottom electrode 182 may include a noble metal, such as ruthenium or iridium.

The seed pattern 184, the ferroelectric pattern 186, and the upper electrode 188 cover an upper surface and sidewalls of the bottom electrode 182, which is protrudes over the blocking layer 170. The ferroelectric pattern 186 may include a ferroelectric material, such as PZT (PbZrTiO). The seed pattern 184 may include a material, which is capable of growing and crystallizing a ferroelectric material. For example, the seed pattern 184 may include iridium. The upper electrode 188 may include a noble metal, such as iridium.

A protecting layer 190 is arranged to cover the capacitor 180 on the substrate 110. The protecting layer 190 may prevent and/or inhibit a gas, such as oxygen or hydrogen, from permeating into the ferroelectric layer 186 and from lowering a ferroelectric characteristic. The protecting layer 190 may include aluminum oxide and/or silicon oxynitride.

According to some embodiments of the present invention, because the bottom electrode 182 protrudes over the blocking layer 170, an effective area where electric charges are stored may be increased. Therefore, it may be possible to embody a highly-integrated ferroelectric capacitor 180 having an increased capacitance.

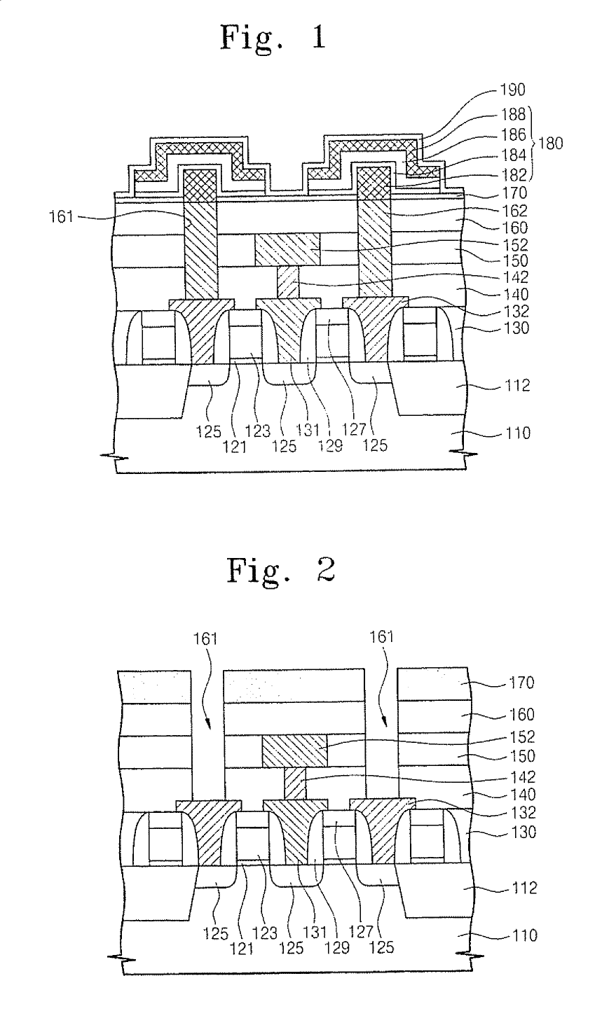

FIGS. 2 through 5 are sectional views illustrating methods of forming a ferroelectric memory device according to some embodiments of the present invention.

Referring to FIG. 2, a device isolation region 112 is formed in the semiconductor substrate 110 to define an active region. A gate insulation layer 121, a gate electrode 123, and a capping layer 127 are formed on the active region. Impurity-doped regions 125 are formed in the active region at both sides of the gate electrode 123. The impurity-doped regions 125 may be referred to as source/drain regions. Spacers 129 are formed at both sidewalls of the gate electrode 123.

A first insulation layer 130 is formed on the semiconductor substrate 110. Contact pads 131 and 132 are formed to contact the impurity-doped regions 125 through the first insulation layer 130. The contact pads 131 and 132 may be formed of a conductive material and formed to be self-aligned to the spacers 129. A second insulation layer 140 and a third insulation layer 150 are formed on the semiconductor substrate 110 having the contact pads 131 and 132. A contact plug 142 is formed in the second insulation layer 140, and a conductive line 152 is formed in the third insulation layer 150. The conductive line 152 may be electrically connected to the contact pad 131 by the contact plug 142. The conductive line 152 and the contact plug 142 may be simultaneously formed, for example, by a dual-damascene process. A fourth insulation layer 160 and a blocking layer 170 are formed on the third insulation layer 150 having the conductive line 152. For example, the insulation layers 130, 140, 150, and 160 may be formed of silicon oxide, and the blocking layer 170 may be formed of titanium oxide, tantalum oxide, and/or silicon nitride. The insulation layers 140, 150, and 160 and the blocking layer 170 are patterned to form an opening 161 exposing the contact pad 132.

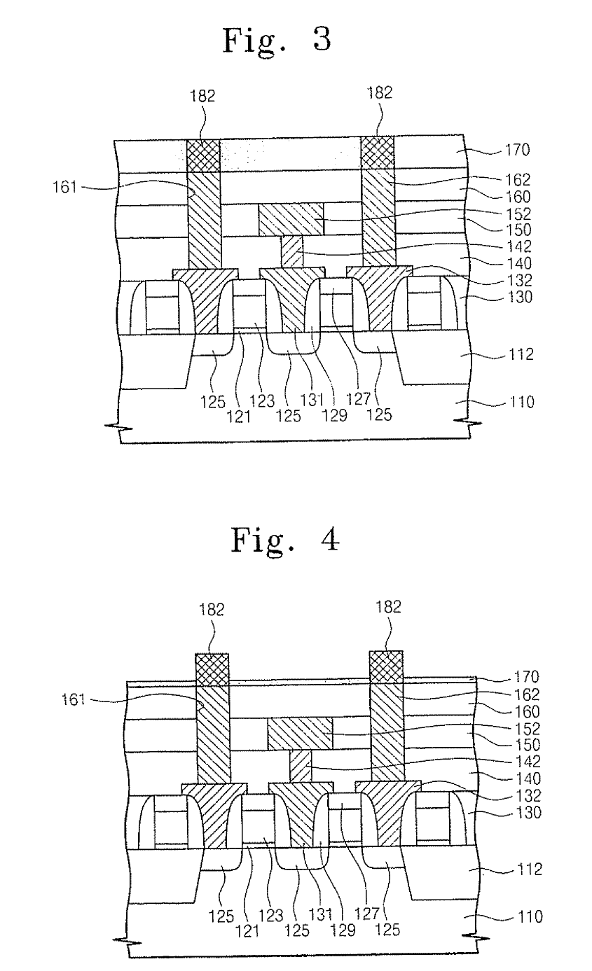

Referring to FIG. 3, a bottom electrode contact 162 is formed to contact the contact pad 132 in the opening 161. To form the bottom electrode contact 162, a conductive material, such as tungsten or a doped polysilicon, is formed to fill the opening 161 and then recessed. An upper surface of the bottom electrode contact 162 may be lower than or have about the same height as a bottom surface of the blocking layer 170.

A bottom electrode 182 is formed on the bottom electrode contact 162. To form the bottom electrode 182, a noble metal material, such as ruthenium or iridium, is formed to fill the opening 161 on the bottom electrode contact 162, and then, a planarization process is performed with respect to the noble metal to expose an upper surface of the blocking layer 170.

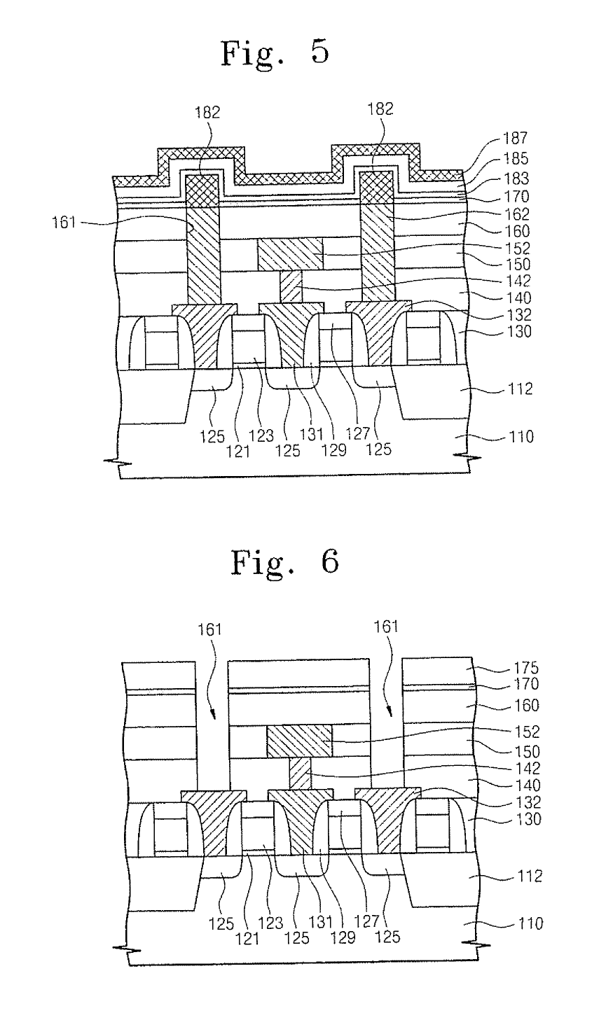

Referring to FIGS. 4 and 5, an etch process is performed to recess the blocking layer 170. The bottom electrode 182 protrudes over an upper surface of the recessed blocking layer 170 and sidewalls of the bottom electrode 182 are exposed.

A seed layer 183 is formed to cover an upper surface and sidewalls of the bottom electrode 182 protrude over the recessed blocking layer 170. The seed layer 170 may be formed of a material, which can grow and crystallize a ferroelectric material, for example, such as iridium.

A ferroelectric layer 185 is formed on the seed layer 183. The ferroelectric layer 185 may be formed of a ferroelectric material, such as PZT, and the upper electrode layer 187 may be formed of a noble metal material, such as iridium. The blocking layer 170 may function so as to protect the layers under the blocking layer 170 when forming the ferroelectric layer 185. For example, when a PZT layer is formed on the seed layer 183 by a metal-organic chemical vapor deposition (MOCVD) process, process sources and/or process gases, such as plumbum (Pb) and/or oxygen, react with the layers under blocking layer 170, thereby causing a lifting or oxidation of the layers. However, the blocking layer 170 can prevent and/or inhibit the process sources and/or process gases from reacting with the layers under the blocking layer 170, so that problems such as the lifting or the oxidation do not occur. An upper electrode layer 187 is formed on the ferroelectric layer 185. The upper electrode layer 187 may be formed of a noble metal material, such as iridium.

Referring to FIG. 1, the upper electrode layer 187, the ferroelectric layer 185, and the seed layer 183 are patterned for an upper electrode 188, a ferroelectric pattern 186, and a seed pattern 184. Therefore, a capacitor 180 is formed to include the bottom electrode 182, the seed pattern 184, the ferroelectric pattern 186, and the upper electrode 188. A protecting layer 190 is formed over the semiconductor substrate 110 having the capacitor 180. The protecting layer 190 may be formed of aluminum oxide and/or silicon oxynitride.

According to some embodiments of the present invention, because a bottom electrode is formed prior to etching the ferroelectric layer 185 and the upper electrode layer 187, an etching time of the ferroelectric pattern 186 may be remarkably shortened. Therefore, the ferroelectric pattern 186 may suffer little etch-damage to elevate a ferroelectric characteristic.

FIGS. 6 through 8 are sectional views illustrating methods of forming a ferroelectric memory device according to other embodiments of the present invention.

Referring to FIG. 6, in contrast to the above-mentioned embodiments, a blocking layer 170 and a sacrificial insulation layer 175 are formed on the fourth insulation layer 160. The sacrificial insulation layer 175 may be formed of for example, silicon oxide. The sacrificial insulation layer 175, the blocking layer 170, and the insulation layers 140, 150, and 160 are patterned to form an opening 161 exposing a contact pad 132.

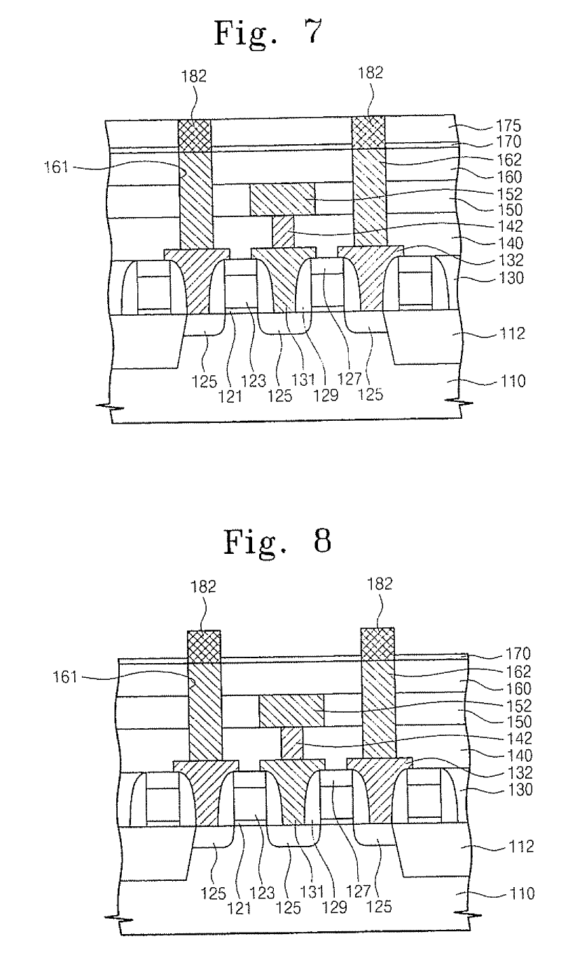

Referring to FIG. 7, a bottom electrode contact 162 is formed to contact the contact pad 132 in the opening 161. To form the bottom electrode contact 162, a conductive material, such as tungsten or a doped polysilicon may be formed to fill the opening 161 and then recessed. An upper surface of the bottom electrode contact 162 may be lower than or have about the same height as a bottom surface of the blocking layer 170.

A bottom electrode 182 is formed on the bottom electrode contact 162. To form the bottom electrode 182, a noble metal, such as ruthenium or iridium, may be formed to fill the opening 161 on the bottom electrode contact 162, and then, a planarization process may be performed with respect to the noble metal to expose an upper surface of the sacrificial insulation layer 175.

Referring to FIG. 8, a sacrificial insulation layer 175 is removed by an etching process. The bottom electrode 182 protrudes over an upper surface of the blocking layer 170, and sidewalls of the bottom electrode 182 are exposed. Alternatively, the sacrificial insulation layer 175 may not be entirely removed but at least a portion thereof may be left to remain. Subsequent processes may be identical to those described in the above-mentioned embodiments.

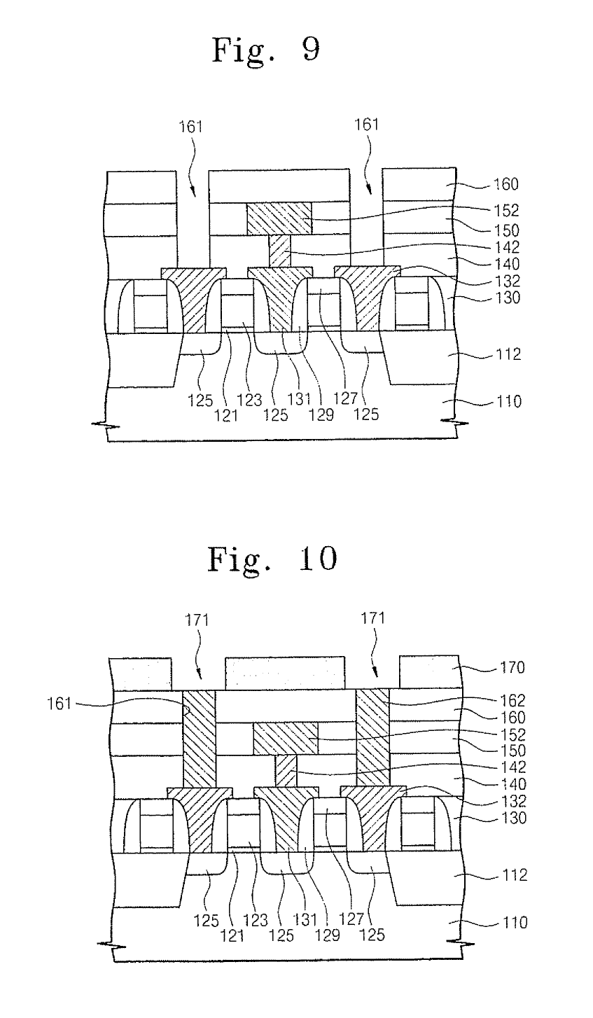

FIGS. 9 through 11 are sectional views illustrating methods of forming a ferroelectric memory device according to other embodiments of the present invention.

Referring to FIG. 9, in contrast to the above-mentioned embodiments, after forming a fourth insulation layer 160, before forming a blocking layer 170, a first opening 161 is formed. That is, the insulation layers 140, 150, and 160 are patterned to form the first opening 161 exposing a contact pad 132.

Referring to FIG. 10, a bottom electrode contact 162 is formed to contact pad 132 in the first opening 161. To form the bottom electrode contact 162, a conductive material, such as tungsten or a doped polysilicon, may be formed to fill the first opening 161, and then, a planarization process may be performed with respect to the conductive material to expose the fourth insulation layer 160. Furthermore, a process of recessing the bottom electrode contact 162 may also be performed. Therefore, an upper surface of the bottom electrode contact 162 may be lower than or have about the same height as an upper surface of the fourth insulation layer 160.

A blocking layer 170 is formed on the fourth insulation layer 160. The blocking layer 170 may be formed of titanium oxide, tantalum oxide, and/or silicon oxynitride. Then, the blocking layer 170 is patterned to form a second opening 171 exposing the bottom electrode contact 162. A width of the second opening 171 may be greater than or about the same as a width of the first opening 161, which is identical to a width of the bottom electrode contact 162.

Referring to FIG. 11, a bottom electrode 182 is formed to contact the bottom electrode contact 162 in the second opening 171. To form the bottom electrode 182, a noble metal, such as ruthenium or iridium, may be formed to fill the second opening 171, and then, a planarization process may be performed with respect to the noble metal to expose an upper surface of the blocking layer 170. Subsequent processes may be identical to those described in the above-mentioned embodiments.

In the present embodiments of FIGS. 9-11, a width of the bottom electrode 182 may be greater than a width of the bottom electrode contact 162, so that a surface area of the bottom electrode 182 may be increased. Therefore, capacitance may be increased.

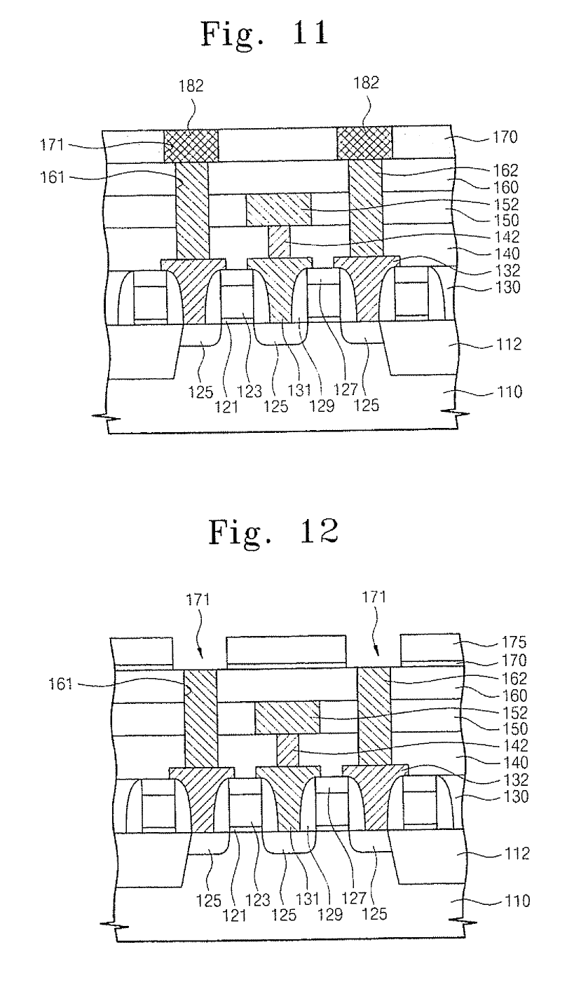

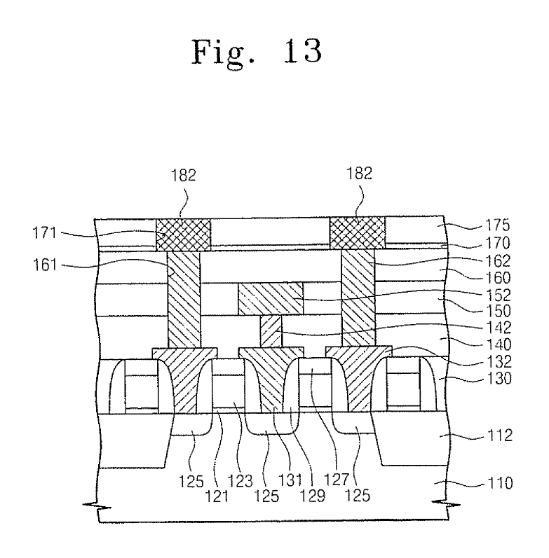

FIGS. 12 and 13 are sectional views illustrating methods of forming a ferroelectric memory device according to other embodiments of the present invention.

Referring to FIG. 12, in contrast to the embodiments of FIGS. 9 and 10, a blocking layer 170 and a sacrificial insulation layer 175 are formed on a fourth insulation layer 160. The sacrificial insulation layer 175 may be formed of silicon oxide. The sacrificial insulation layer 175 and the blocking layer 170 are patterned to form a second opening 171 to expose the bottom electrode contact 162. A width of the second opening 171 may be wider than or about the same as a width of the first opening 161, which is identical to a width of the bottom electrode contact 162.

Referring to FIG. 13, a bottom electrode 182 is formed to contact the bottom electrode contact 162 in the second opening 171. To form the bottom electrode 182, a noble metal, such as ruthenium or iridium, may be formed to fill the second opening 171, and then, a planarization process may be performed with respect to the noble metal to expose an upper surface of the sacrificial insulation layer 175. Subsequent processes may be identical to those explained in the above-mentioned embodiments.

According to embodiments of the present invention, it is possible to form a ferroelectric capacitor which protrudes over a blocking layer and/or insulation layers into a three-dimensional structure. Therefore, an effective area of the capacitor where electrical charge is stored may be enlarged to increase the capacitance, and the ferroelectric memory device may be highly integrated. Furthermore, the ferroelectric capacitor may have a ferroelectric pattern with better characteristics. Therefore, reliability and operation characteristics of the ferroelectric memory device may be improved.

In concluding the detailed description, it should be noted that many variations and modifications can be made to the embodiments without substantially departing from the principles of the present invention. All such variations and modifications are intended to be included herein within the scope of the present invention, as set forth in the following claims.

That which is claimed:

1. A method of forming a ferroelectric memory device, comprising:
forming an insulation layer on a substrate having a conductive region;
forming a bottom electrode electrically connected to the conductive region in the insulation layer;
recessing the insulation layer; and
forming a ferroelectric layer and an upper electrode layer covering the bottom electrode on the recessed insulation layer;
wherein the bottom electrode protrudes over an upper surface of the recessed insulation layer.

2. The method of claim 1, wherein forming the insulation layer comprises:
forming an interlayer dielectric layer on the substrate; and
forming a blocking layer on the interlayer dielectric layer.

3. The method of claim 2, wherein forming the bottom electrode comprises:
patterning the interlayer dielectric layer and the blocking layer to form an opening exposing the conductive region;
forming a bottom electrode contact contacting the conductive region in a lower region of the opening; and
filling the opening on the bottom electrode contact with a conductive material.

4. The method of claim 2, wherein forming the bottom electrode comprises:
patterning the interlayer dielectric layer to form a first opening exposing the conductive region;
forming a bottom electrode contact contacting the conductive region in the first opening;
forming a blocking layer on the interlayer dielectric layer where the bottom electrode contact is formed;
patterning the blocking layer to form a second opening exposing the bottom electrode contact; and
filling the second opening with a conductive material.

5. The method of claim 4, wherein a width of the second opening is greater than a width of the first opening.

6. The method of claim 2, wherein recessing the insulation layer comprises recessing the blocking layer.

7. The method of claim 1, wherein forming the insulation layer comprises;
forming an interlayer dielectric layer on the substrate;
forming a blocking layer on the interlayer dielectric layer; and
forming a sacrificial insulation layer on the blocking layer.

8. The method of claim 7, wherein forming the bottom electrode comprises,
pattering the interlayer dielectric layer, the blocking layer, and the sacrificial insulation layer to form an opening exposing the conductive region;
forming a bottom electrode contact contacting the conductive region in a lower region of the opening; and
filling the opening on the bottom electrode contact with a conductive material.

9. The method of claim 7, wherein forming the bottom electrode comprises:
patterning the interlayer dielectric layer to form a first opening exposing the conductive region;
forming a bottom electrode contact in the first opening;
forming the blocking layer and the sacrificial insulation layer on the interlayer dielectric layer where the bottom electrode contact is formed;
patterning the blocking layer and the sacrificial insulation layer to form a second opening exposing the bottom electrode contact; and
filling the second opening with a conductive material.

10. The method of claim 9, wherein a width of the second opening is greater than a width of the first opening.

11. The method of claim 7, wherein recessing the insulation layer comprises recessing the sacrificial insulation layer.

12. The method of claim 7, wherein recessing the insulation layer comprises removing the sacrificial insulation layer.

13. The method of claim 1, further comprising:
forming a seed layer for growing the ferroelectric layer before forming the ferroelectric layer.

14. A ferroelectric memory device comprising:
a substrate having a conductive region;
an insulation layer on the substrate;
a bottom electrode that is electrically connected to the conductive region and protrudes over the insulation layer, the bottom electrode having a bottom surface that is lower than an upper surface of the insulation layer; and
a ferroelectric layer and an upper electrode that cover an upper surface and sidewalls of the bottom electrode.

15. The ferroelectric memory device of claim 14, further comprising:
a bottom electrode contact interposed between the conductive region and the bottom electrode, wherein a width of the bottom electrode is about the same as a width of the bottom electrode contact.

16. The ferroelectric memory device of claim 14, wherein the bottom electrode has a constant width.

17. The ferroelectric memory device of claim 14, wherein the bottom electrode comprises ruthenium or iridium.

18. The ferroelectric memory device of claim 14, wherein the insulation layer comprises an interlayer dielectric layer and a blocking layer on the interlayer dielectric layer, and a bottom surface of the bottom electrode is lower than or has about the same height as a bottom surface of the blocking layer.

19. The ferroelectric memory device of claim 18, wherein the blocking layer comprises titanium oxide, tantalum oxide, and/or silicon nitride.

20. The ferroelectric memory device of claim 14, wherein the ferroelectric layer comprises a seed layer.
